(19) United States
(12) Patent Application Publication
(10) Pub. No.: US 2011/0074005 A1
(43) Pub. Date: Mar. 31, 2011

(54) SEMICONDUCTOR DEVICE, METHOD FOR FABRICATING A SEMICONDUCTOR DEVICE AND LEAD FRAME, COMPRISING A BENT CONTACT SECTION

(76) Inventor: Peter Kirk Jaeger, BP Dussen (NL)

(21) Appl. No.: 12/894,797

(22) Filed: Sep. 30, 2010

(30) Foreign Application Priority Data
Sep. 30, 2009 (EP) 09012416.5

(51) Int. Cl. H01L 23/48; H01L 21/60

(52) U.S. Cl. 257/690; 438/123; 257/E21.506; 257/E23.01

(57) ABSTRACT

The invention relates to a semiconductor device having an integrated circuit die and a housing. The housing includes a base surface and at least one lateral surface which extends across to the base surface. In particular, this semiconductor device can be an electronic chip card, such as a universal integrated circuit card (UICC). The semiconductor device includes at least one electrical contact for electrically connecting the integrated circuit die with an abutting counter contact of a connecting device. The electrical contact has first and second mating sections, which are arranged on the base surface and lateral surface, respectively, and are connected to each other through a bent section.

### CROSS-REFERENCE TO RELATED APPLICATIONS

This application claims priority under 35 U.S.C. §119 to European Patent Application No. EP 09012416.5, filed Sep. 30, 2009.

### FIELD OF THE INVENTION

The invention relates to a semiconductor device, and in particular, to a semiconductor device having an integrated circuit die and a housing

### BACKGROUND

Electronic chip cards such as integrated circuit cards have been constantly developed and improved in the past years. In particular, their form factor was adapted to the new market requirements so that the overall dimensions of an electronic card in use today could be reduced, for instance, down to 12 mm×15 mm for a mini UICC (Universal Integrated Circuit Card), which generally have dimensions of 5 mm×6 mm×0.85 mm. These cards can include memory circuits and control circuits and can be easily integrated in small size devices or electronic circuitry, such as the onboard system of a car or a machine for performing dedicated tasks.

A possible application for electronic cards is the automatic exchange of information between two or more end devices in order to allow remote monitoring, control or maintenance of machines or systems. In general, electronic cards with reduced dimensions are widely used in all kinds of so called machine to machine applications. Furthermore, it is known to use cards in mobile telephones, personal digital assistants, radio modems, and radio modules according to the GSM mobile standard (global system for mobile communication) or the UMTS mobile standard (universal mobile telecommunications system) in order to identify the user of the mobile terminal within the mobile network. These chip cards are plugged into the user equipment in order to read out the data stored thereon.

FIG. 16 shows a slide-in connecting device for connecting a known UICC 200, manufactured by a conventional laminate frame (lamframe) process, to internal device contacts 142 of the user equipment. As shown schematically in FIG. 16, electric contacts 204 of the UICC 200 are positioned on a base surface 202 of the card housing, and contact sharp edges 201 of the internal device contact 142. These sharp edges 201 in current lamframe layouts are prepared by a cutting step on the outside of the separated chip cards, and may lead to connector contact wear and also to corrosion. This causes connection reliability problems.

Furthermore, the package of the conventional chip card 200 is fabricated by overmolding a plated metal strip and then separating these contacts by cutting same. In a next fabrication step, the integrated circuit die is placed and wired bonded and, finally, a second overmold closes the package, but leaves open the contacts 204. As can be seen from FIG. 16, at the edge 201, the contact 204 is not only very sharp, but also is not covered by the gold plating step, because the cutting is performed after plating the contacts; therefore corrosion may occur in the region 201.

Generally, chip cards are required to comply with a number of different requirements depending on the particular field of application. For instance, with respect to modem applications, chip cards comply with industrial and environment standards (i.e. requires IP20 dust protection), higher operating temperatures, and automatic pick and place. With respect to a localization application, the size of chip cards is an important criteria, as well as alternative connector application style. In automotive applications, reliability is a significant requirement, especially within a harsh environment (vibration and shock).

Consequently, a semiconductor device, in particular, a chip card and a belonging method of fabrication is needed, which improves the quality, stability and reliability of electrical connection to counter contacts of an electronic device.

### SUMMARY

Therefore, the invention has been made in view of the above problems, and it is an object of the invention to provide a semiconductor device based on an overmolding a stamped strip instead of the known laminated strips, the so-called lamframes.

In particular, the semiconductor device includes a housing, an integrated circuit die, and a contact. The housing has a base surface and a lateral surface which extends to the base surface. The integrated circuit die is positioned on an inside of the housing. While the contact includes a first mating section, a second mating section, and a bent section. The first and second mating sections are arranged on the base surface and lateral surface, respectively, and are connected to each other via the bent section.

### BRIEF DESCRIPTION OF THE DRAWINGS

The foregoing and other features of the invention will now be described with reference to the accompanying drawings. In the drawings, the same components have the same reference numerals. The drawings are incorporated into and form a part of the specification for the purpose of explaining the principles of the invention. However, the drawings are not to be construed as limiting the invention to only the illustrated and described examples of how the invention can be used and made. Moreover, different aspects and details of the embodiments explained in the following may form inventive solutions in alternative combinations or arrangements. Further features and advantages will become apparent from the following and more detailed description of the invention which is illustrated in the accompanying drawings, wherein:

FIG. 1 is a perspective view of a base surface of a semiconductor device according to the invention, having been fully assembled;

FIG. 2 is a perspective view of a top surface of the semiconductor device of FIG. 1;

FIG. 3 is a perspective of the chip card of FIG. 2, showing an inside view of the semiconductor device;

FIG. 4 is a perspective view of a lead frame according to the invention in a first manufacturing step;

FIG. 5 is a perspective view of the lead frame of FIG. 4 after bending contacts of the semiconductor device according to the invention;

FIG. 6 is a perspective of the lead frame of FIG. 5 after providing insulation elements to support and insulate the contacts;

FIG. 7 is perspective view of the lead frame of FIG. 6 after punching slots that separate the contacts from each other and from a die attach pad;

FIG. 8 is a perspective view of the lead frame of FIG. 7 after attaching a integrated circuit die;

FIG. 9 is a perspective view of the lead frame of FIG. 8 after providing wire bond connections between the integrated circuit die and the contacts;

FIG. 10 is a perspective view of another lead frame according to the invention;

FIG. 11 is a perspective view of base surface of another semiconductor device according to the invention;

FIG. 12 is a perspective view of a top surface of the semiconductor device of FIG. 11;

FIG. 13 is a perspective view of the semiconductor device of FIG. 12, showing an inside view of the semiconductor device;

FIG. 14 is a sectional view of a connecting device for the a semiconductor device according to the invention;

FIG. 15 is a sectional view of another connecting device for the a semiconductor device according to the invention; and

FIG. 16 is a sectional view of a slide-in connecting device for connecting a conventional chip card.

### DETAILED DESCRIPTION OF THE EMBODIMENT(S)

FIG. 1 shows in a perspective view a semiconductor device, such as a micro universal integrated circuit card (UICC) 100, according to the invention. Of course, the inventive concept can be used with any other integrated circuit package which is intended to be brought into contact with belonging contacts or to be soldered to a substrate. The micro UICC 100 is shown in FIG. 1, with the contact carrying base surface 102 facing upward in order to illustrate more clearly the contacts 104. According to the invention, each contact 104 includes a first mating section 108 in plane with the base surface 102, and a second mating section 110 that extend across to the first mating sections 108 and are arranged along a lateral surface 106.

A bent section 112 connects the first and second mating sections 108, 110 to each other. According to the shown embodiment, this bent section 112 is prepared as a curved section. The design of such a contact 104 allows for slide-in application contacting with minimal wear. However, the bent section 112 can also have other suitable shapes, such as a combination of two 45° bends with a short straight portion there between. Further, the bent region here results in an essentially perpendicular arrangement of the first and second mating surfaces 108, 110 with respect to each other, but any other angle between the first and second mating surfaces 108, 110 can also be formed according to the invention. As is clear from FIG. 1, the bent section 112 is a smooth bent section with no discontinuous formations, thereby forming a cross-over between the first and second mating surfaces 108, 110, being free of any sharp edges. In particular, the bent section 112 is configured as a continuous region, such that the cross-over between the first and second mating sections 108, 110 is a smooth cross-over with no discontinuous formations. Accordingly, by providing a continuous cross-over the formation of a sharp-edge between said first and second mating sections 108, 110 is avoided. The advantage thereof is among others an increased reliability, since the wear of a chip or counter contact can be reduced.

As will become more apparent from FIG. 3, the contacts 104 are electrically insulated from each other and mechanically supported by an insulating element 114. The insulating element 114 can for instance be manufactured by an injection molding step.

A cooling surface 116 of a die attach pad 118 extends to the outside of the semiconductor device, micro UICC 100, in order to operate as a heat sink. When the micro UICC 100 is directly soldered, for instance, to a printed circuit board (PCB), the cooling surface 116 can be soldered to a belonging copper surface of the printed circuit board to provide a heat sink function and quickly dissipate heat generated by the integrated circuit die 124.

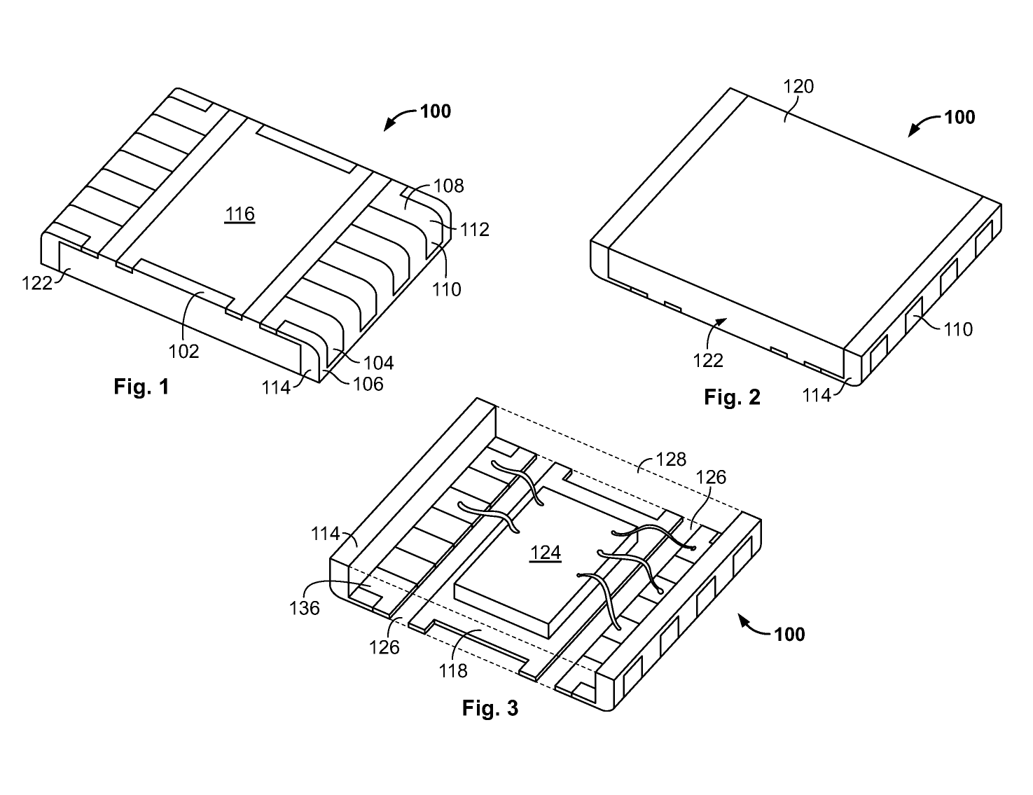

As shown in FIG. 2, a cover 120 closes the housing 122. This cover 120 is for instance formed by a plastic material that is overmolded in order to tightly close the housing 122. As the surface of the cover 120 is completely smooth, it offers the advantage of representing a relatively large and well-defined pick-and-place area for an automatic placement machine.

In FIG. 3, the micro UICC 100 is shown without the material of the cover 120 in order to explain the inner structure of the micro UICC 100. On the inside of the housing 122, the integrated circuit die 124 is attached to the die attach pad 118. The integrated circuit die 124 can be fixed to the die attach pad 118 by many known techniques, such as gluing, soldering or the like. The electrical connections between the integrated circuit die 124 and bond pads 136 of the contacts 104 can, for instance, be established by wire bonding. As will be apparent from the description of the manufacturing steps, small, sharp edges resulting from cutting and stamping a metal lead frame are either completely covered by the cover material 120 along a insulating sections 126 between the contacts 104 and the die attach pad 118. Alternatively, sharp edges are only to be found on surfaces which are not critical for electrical connections, such as the second lateral surfaces 128.

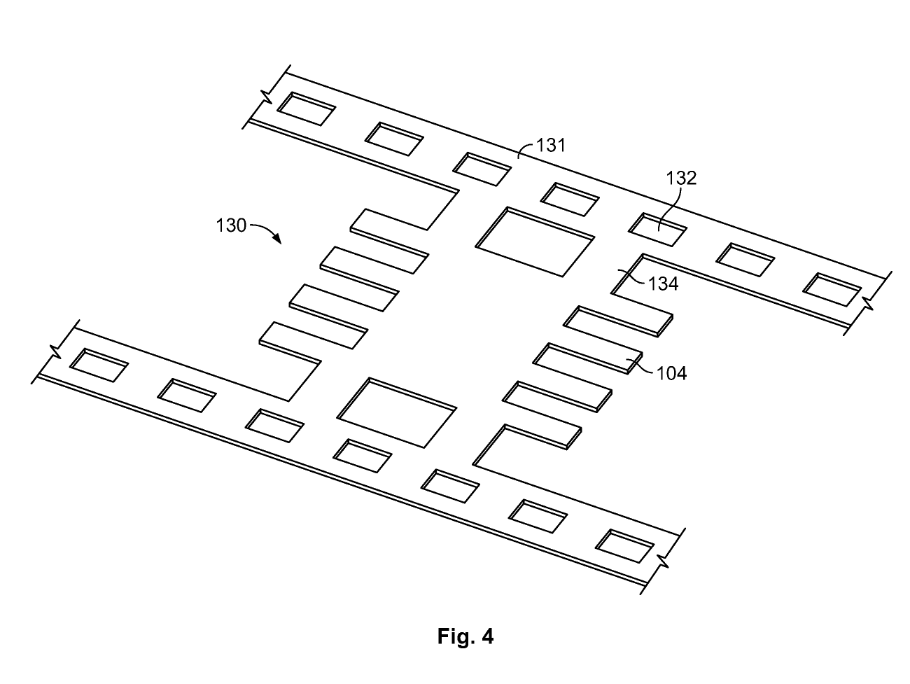

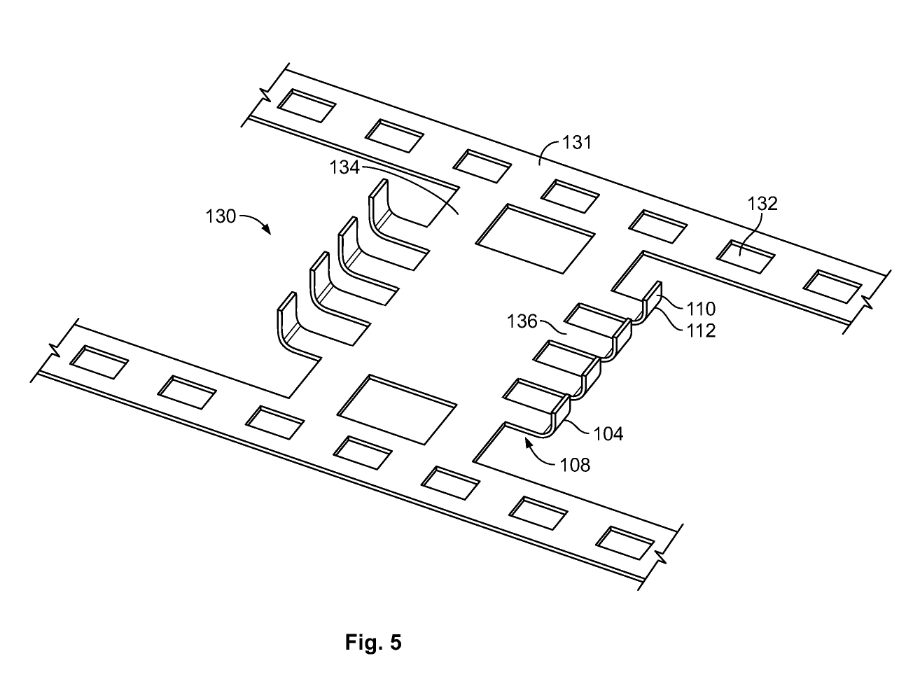

With reference to FIGS. 4 to 9, the manufacturing process of semiconductor devices according to the invention, such as a micro UICC 100, from a lead frame 130 will be explained in detail. The lead frame 130 is part of a carrier strip in a reel-to-reel process suitable for fully automated manufacturing. As shown in FIG. 4, a first stamping process is performed to provide the contacts 104 and further provide webs 134 for fixing the lead frame on the carrier 131 of the strip. Sprocket holes 132 are provided for the processing in a reel-to-reel process.

Next, a bending step follows, which provides the bent section 112 and forms the contacts 104 to have the first and second mating sections 108, 110 that extend across to each other. However, any other profiles of the bent section 112 can also be fabricated during this step.

After the forming step, the first and second mating sections 108, 110 of the contacts 104 can be plated with an electrically conductive and/or corrosion stable film, such as gold. Of course, all usual deposition techniques and materials for forming such a plating layer can be applied. The bending process also has the advantage that a selective galvanic plating process can be performed.

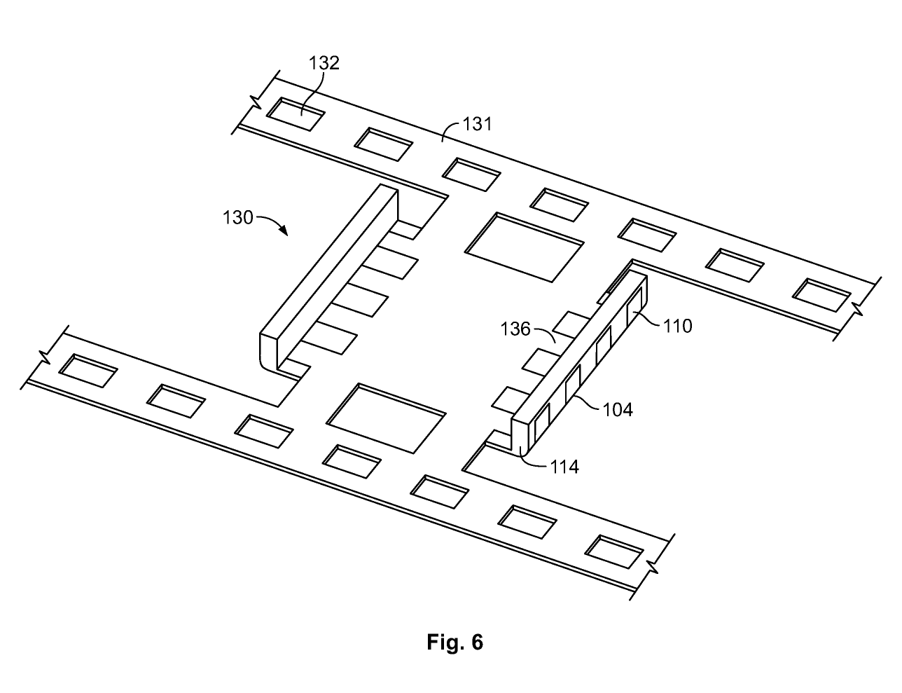

FIG. 6 shows the lead frame 130 after a first overmolding step wherein the insulating elements 114 are formed. The contacts 104 together with their radius are embedded and supported in the material of the insulating element 114 during this overmolding step.

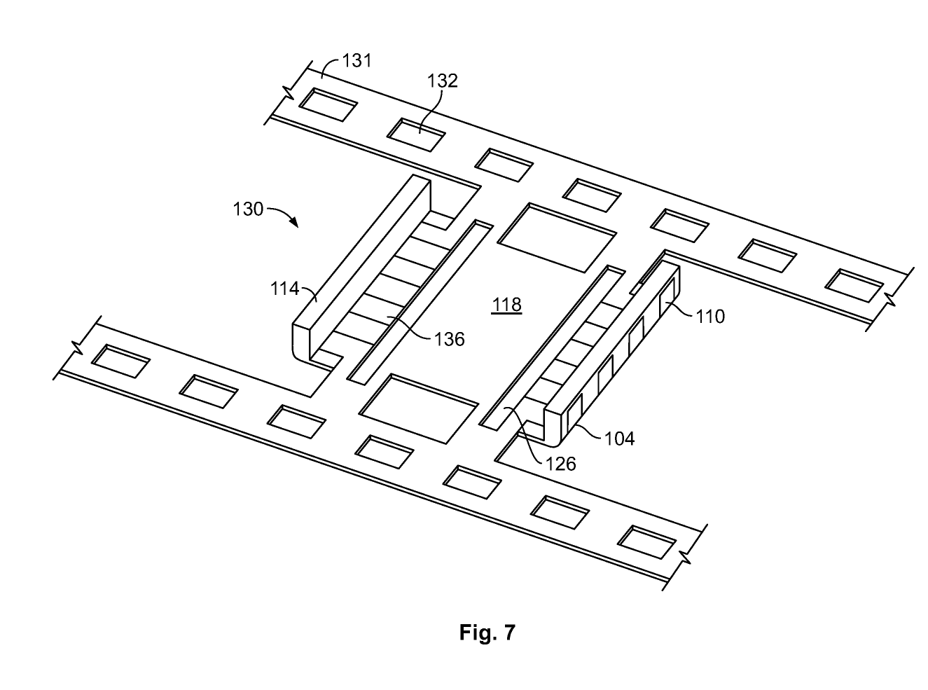

Subsequently, a further punching step can be performed in order to separate the contacts 104 from each other, which are mechanically fixed within the insulating element 114. The stamped slots form the insulating section 126 between the die attach pad 118 and the contacts 104 in the finally mounted state (see FIG. 7).

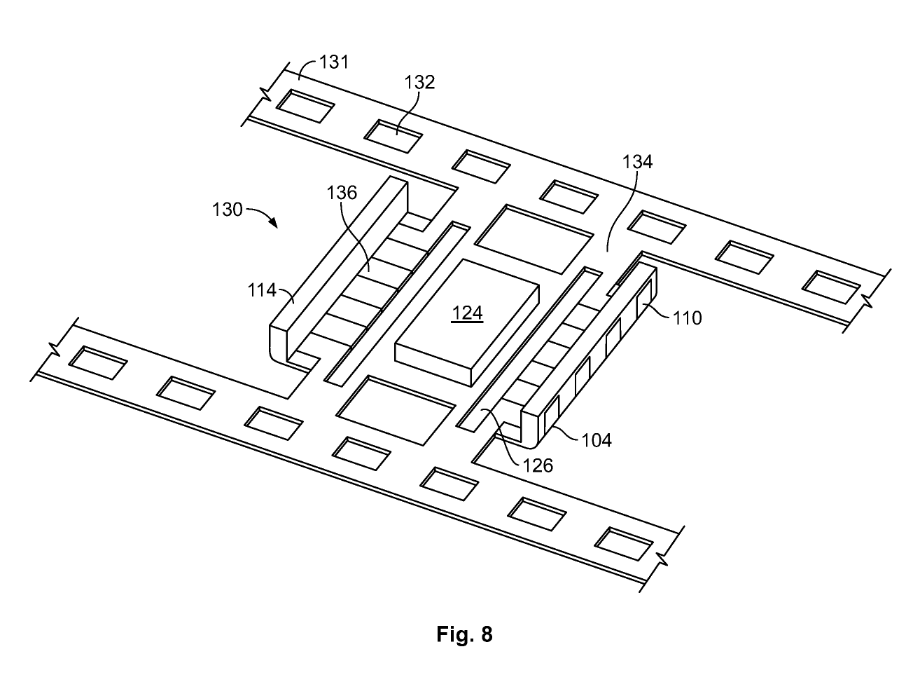

By conventional die attaching techniques, the integrated circuit die 124 is attached to the die attach pad 118, as can be seen from FIG. 8. However, carrier strips, not having an installed integrated circuit die 124, can also be kept on stock and transferred to a customer in the form they have in FIG. 7.

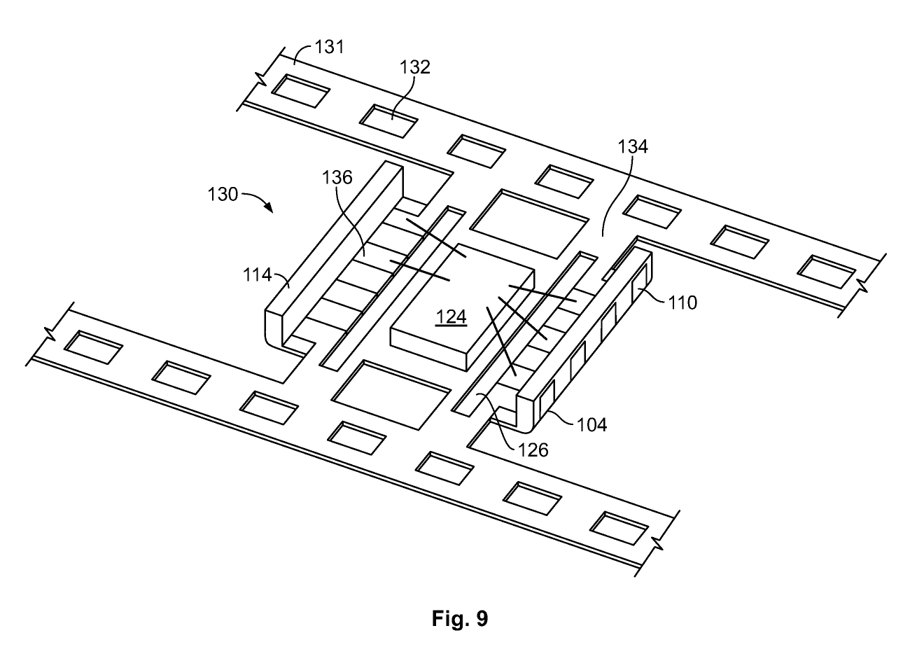

As shown in FIG. 9, a wire bonding step is performed to provide electrical connection between the integrated circuit die 124 and bond pads 136 of the contacts.

Before the webs 134 are cut and the semiconductor devices are separated, thereby forming the individual micro UICCs 100, the cover 120 is added, which is shown in FIGS. 1 and 2. The cover 120 can be produced by a second overmolding step or by potting, filling or encapsulation steps, or by mounting a cover 120. This assembly step can also be performed by a customer.

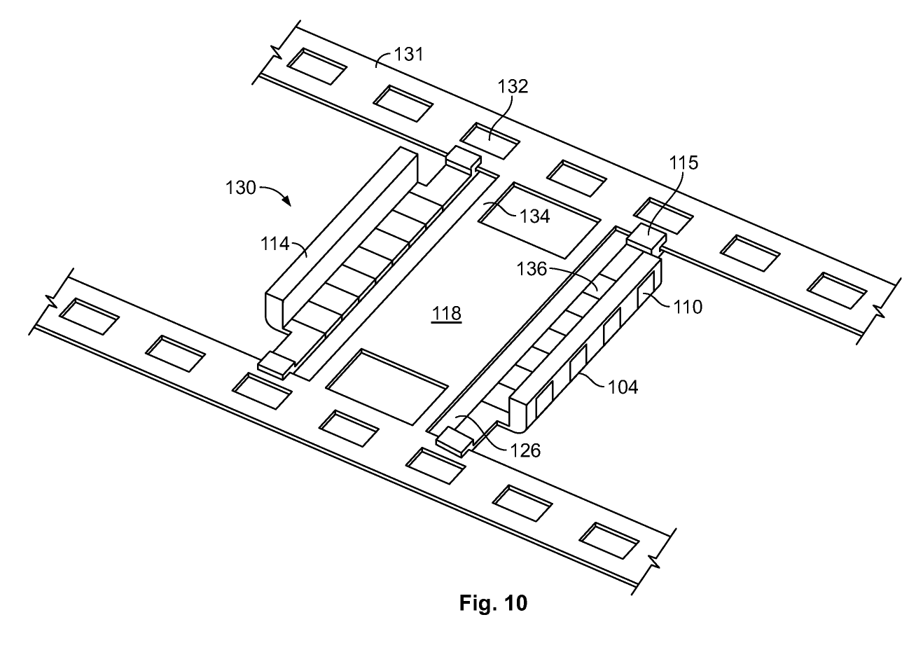

FIG. 10 shows another embodiment of a lead frame 130 structure used to manufacture a semiconductor device according to the invention, where, instead of the metallic webs 134 that establish an electrical contact between the outside carrier 131 and the contacts 104, a non-conductive link 115 to the strip is provided by mounting the contacts 104 as a separate part embedded within the insulating element 114. This embodiment can replace the embodiment of FIG. 7. Due to the non-conductive fixing means 115, a test of the electrical connections between the bond pads and the integrated circuit die 124 can be performed on the strip without the necessity of isolating the individual semiconductor devices by cutting them apart, even after attaching the integrated circuit die 124 and performing the wire bonding process.

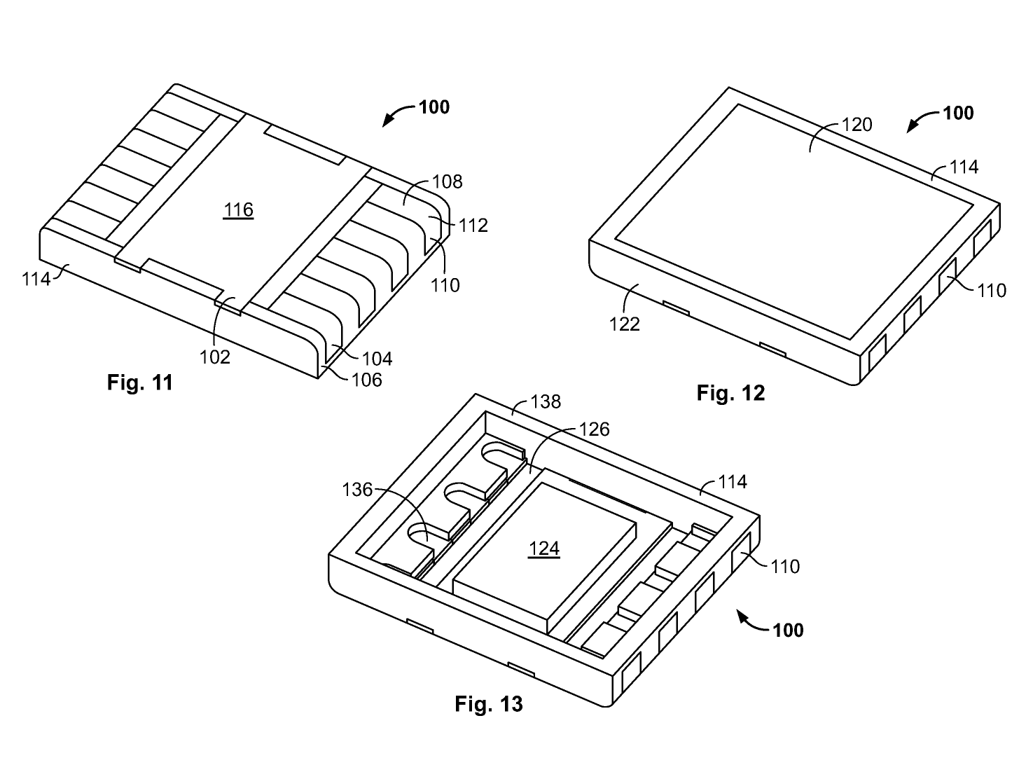

Another embodiment of a semiconductor device according to the invention is shown in FIGS. 11 to 13, where the insulating elements 114 are formed as a frame 138 which encompasses the integrated circuit die 124. Accordingly, the circumferentially closed insulating frame 138 has the advantage that the potting or overmolding process for providing the cover 120 is facilitated.

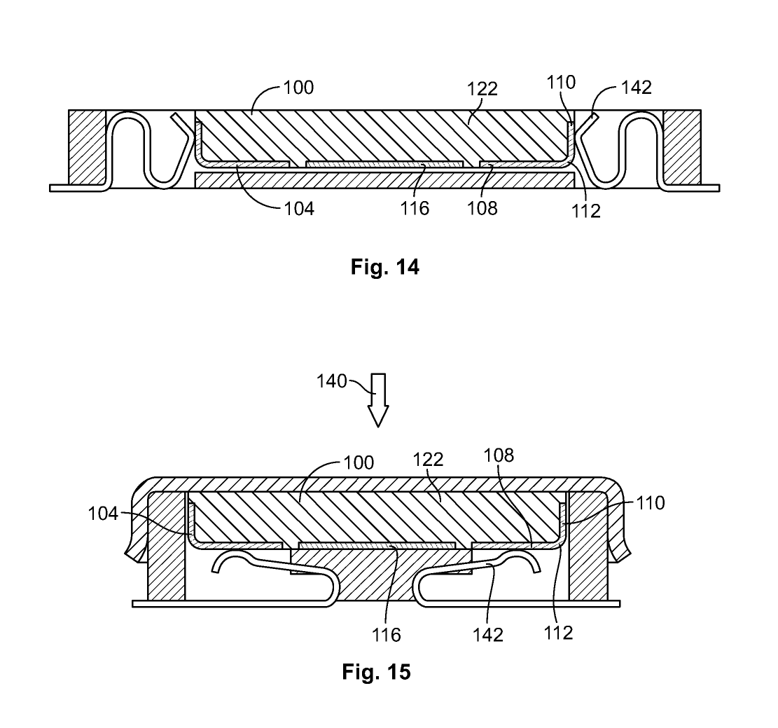

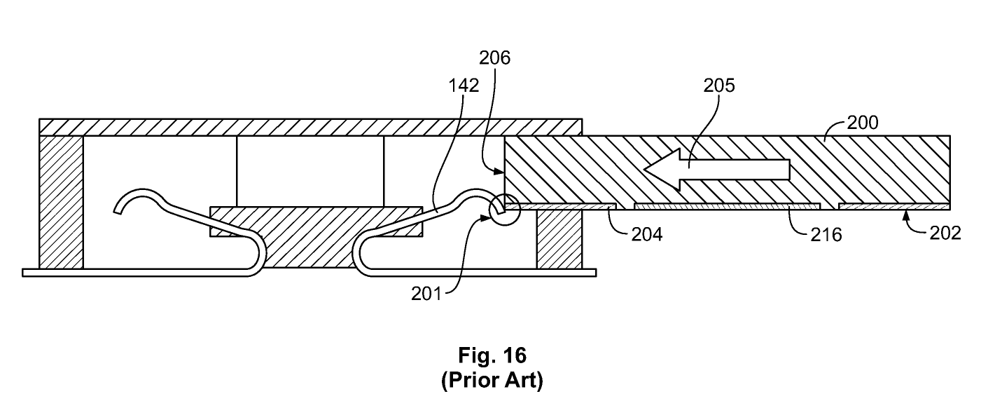

FIGS. 14 and 15 show two possible electrical contacting schemes for the semiconductor device according to the invention, such as a micro UICC 100.

As can be seen from FIG. 14, the second mating section 110 on the lateral surface 106 allows for a contacting by means of a slide-in motion without the necessity of applying a residual pressure in a contacting direction 140. The micro UICC 100 is kept in position by the friction force on the contacts 104. When forming the bent section 112 in a way that the second mating section 110 is bent by more than 90° or includes a recess (not shown) allowing engagement of the counter contact 142, a form fit can be achieved.

The tolerance chain of this arrangement is very short because only the sum of the tolerance of the semiconductor device and of the distance between the counter contacts 142 has to be considered, whereby the reliability can be enhanced. Furthermore, this sort of contacting leads to a larger wipe area between the contact 104 and the counter contact 142. A large wipe distance, however, is favourable because it cleans the contact point of any pollution. Furthermore, side contacts according to the invention allow for an ultra low height socket and enhance the reliability of the electric contact. Side contacting schemes moreover allow a fully automated pick and place assembly of the semiconductor device.

Also with a press-in contact, as shown in FIG. 15, a micro UICC 100 according to the invention can easily be used. This arrangement has the advantage that it allows for a very small printed circuit board area. In any case, the inventive side and bottom contacts enhance the design flexibility for a module designer.

By providing a connection surface on the bottom as well as on the side of the housing 122, and by providing a full radius there between, in the case of slide-in contacting, minimal wear can be achieved. Furthermore, the contact 104 edges can also be covered with a metal plating and therefore the reliability of the electric contact 104 is enhanced considerably. Additionally, many different mating directions and contacting schemes are possible. Finally, a higher reliability of the connection due to reduced tolerance chains can be achieved, when using the inventive chip card in sockets with contacts mating on the side contacts of the chip card's package.

A semiconductor device according to the invention which can be used for memory cards, smart cards, ID cards and socketable ICs offers several advantages. Firstly, the semiconductor device according to the invention allows for fully plated contact areas and makes sure that no bare base material of the lead frame 130 is exposed. Further, many different mating directions and principles for the electrical contact 104 to a counter contact 142 are possible. In particular, electrical contact 104 can be established through the two mating surfaces at the bottom and the side surface as well as via the radius of the contact 104.

Slide-in mating motions can be performed with minimal wear to the connector device because sharp edges can be avoided. Finally, high reliability of the connections can be achieved due to reduced tolerance chain in sockets when using the contacts 104 mating on the side contact 104 of the semiconductor package.

According to an advantageous embodiment of the present invention, the housing 122 comprises an electrically insulating cover 120 for protecting and electrically insulating the integrated circuit die 124. This cover 120 can for instance be formed by a further overmolding process. In case that the semiconductor device is directly soldered to a printed circuit board (PCB), the cooling surface 116 can also be soldered to copper surfaces on the PCB which provide heat sink function.

The configurations described in the above-described embodiment can be selected or changed to other configurations as appropriate. Those skilled in the art will appreciate that various modifications, additions and substitutions are possible, without departing from the scope and spirit of the invention as disclosed in the accompanying claims.

What is claimed is:

1. A semiconductor device comprising:
a housing having, a die attach pad, a base surface and a lateral surface which extends to the base surface;
an integrated circuit die positioned on an inside of the housing; and,
a contact having a first mating section, a second mating section, and a bent section, the first and second mating sections are arranged on the base surface and lateral surface, respectively, and are connected to each other via the bent section.

2. The semiconductor device according to claim 1, wherein the contact is stamped and formed from a metal sheet.

3. The semiconductor device according to claim 1, wherein the first and second mating sections are plated with an electrically conductive layer.

4. The semiconductor device according to claim 1, further comprising an insulating element for mechanically securing and electrically insulating the contact.

5. The semiconductor device according to claim 4, wherein the insulating element is formed by over-molding the contact.

6. The semiconductor device according to claim 1, further comprising an insulating section separating the die attach pad from the contact.

7. The semiconductor device according to claim 1, further comprising a cooling surface positioned opposite to a mounting surface whereto the integrated circuit die is attached.

8. The semiconductor device according to claim 7, wherein the cooling surface extends outside the housing for dissipating heat generated by the integrated circuit die.

9. The semiconductor device according to claim 1, wherein the housing includes a cover for protecting said integrated circuit die.

10. The semiconductor device according to claim 9, wherein the cover is made of an electrically insulating material.

11. The semiconductor device according to claim 10, wherein the cover is positioned by an over-molding process.

12. The semiconductor device according to claim 1, wherein the housing is substantially flat.

13. The semiconductor device according to claim 12, further comprising a plurality of contacts positioned according to a Universal Integrated Circuit Card standard.

14. A method for manufacturing a semiconductor device, comprising the steps of:
manufacturing a lead frame having a contact and a die attach pad for attaching an integrated circuit die, the contact electrically connecting the integrated circuit die with an abutting counter contact of a connecting device;
forming a bent section along the contact by bending a stamped portion of the lead frame, the bent section connecting first and second mating sections of the contact, wherein said first and second mating sections extend substantially across to each other.

15. The method of claim 14, further comprising the step of providing an insulating element for mechanically securing and electrically insulating the contact.

16. The method of claim 15, further comprising the step of stamping a slot for separating the contact from the die attach pad.

17. The method of claim 16, further comprising the steps of:
attaching the integrated circuit die to the die attach pad; and
providing an electrical connection between the integrated circuit die and the contact.
A lead frame for mounting an integrated circuit die, comprising:
a die attach pad for attaching the integrated circuit die;
a contact having first and second mating sections which extend substantially across to each other, the contact electrically connects the integrated circuit die with an abutting counter contact of a connecting device; and
a bent section formed from a stamped portion of the lead frame and positioned along the contact, the bent section connects the first and second mating sections.
